(19) United States
(12) Patent Application Publication
(10) Pub. No.: US 2024/0254313 A1
(43) Pub. Date: Aug. 1, 2024

(54) SILICA POWDER IN WHICH AGGREGATION IS REDUCED, RESIN COMPOSITION, AND SEMICONDUCTOR SEALING MATERIAL

(71) Applicant: DENKA COMPANY LIMITED, Chuo-ku, Tokyo (JP)

(72) Inventors: Teruhiro AIKYO, Tokyo (JP); Takaaki MINAMIKAWA, Tokyo (JP); Yasuaki HATAYAMA, Tokyo (JP); Naoto HAYASHI, Tokyo (JP)

(73) Assignee: DENKA COMPANY LIMITED, Chuo-ku, Tokyo (JP)

(21) Appl. No.: 18/560,463

(22) PCT Filed: May 6, 2022
(86) PCT No.: PCT/JP2022/019592

§ 371 Date: Nov. 13, 2023

(30) Foreign Application Priority Data
May 13, 2021 (JP) 2021081341

(51) Int. Cl. C08K 3/36; C01B 33/12; H01L 23/29

(52) U.S. Cl. CPC C08K 3/36; C01B 33/12; H01L 23/295; C01P 2006/12; C08K 2201/005; C08K 2201/006

(57) ABSTRACT

Provided are a silica powder with a particle size of 2.0 μm or less which does not readily aggregate, has favorable handling, and readily disperses when mixed with a resin; and a resin composition and a semiconductor sealing material comprising the silica powder.

The silica powder has a volume-based cumulative size (D50) of 2.0 μm or less and a maximum particle size (Dₘₐₓ) of 5.0 μm or less as measured by a grind gauge with the following method.

(Measurement Method)

The degree of dispersion of the silica powder in the epoxy resin is evaluated in a resin composition obtained by adding 67 parts by mass of the silica powder to 100 parts by mass of a bisphenol F-type liquid epoxy resin with a distribution map method using a grind gauge and the maximum particle size (Dₘₐₓ) is measured in accordance with JIS K 5600-2-5. Further, the same evaluation is performed five times and the average value thereof is employed.

### TECHNICAL FIELD

The present relates to a silica powder in which aggregation is reduced, a resin composition, and a semiconductor sealing material.

### BACKGROUND ART

In silica powders used in semiconductor sealing material applications, insulated substrate applications, and the like, aggregated particles and coarsened particles are causes of damage to packages, short circuits in lead wires, substrate surface irregularities, white spots, and the like, so the reduction thereof is desired. Further, when a silica powder comprising coarse particles has been blended with a resin, this is a cause of lowered fluidity of the resin and damage to semiconductors, molding defects, and the like readily occur when using such a resin composition as a semiconductor sealing material. From these perspectives, a silica powder with few coarse particles and which does not readily aggregate is desired.

Incidentally, it is known that aggregation readily occurs in silica powders with an average particle size of 2.0 μm or less due to the relationship between forces acting on the silica powder (weight, liquid crosslinking force, van der Waals force, etc.). Adhesion to devices or containers is also high in silica powders having such a particle size, so there is also the problem of handling being poor due to the silica powder clogging transport piping or feeders. From such background, the yield of silica powders with a particle size of 2.0 μm or less in classification with sieves or the like is extremely poor and the manufacture of silica powders with few coarse particles is difficult. Further, aggregation and coarsening also occur with vibration due to sieve devices, so there is also the problem of the desired dispersibility not readily being obtained when mixed with a resin.

In recent years, thinning of elements, reductions in metal wiring diameters, lengthening of spans, increases in wiring pitch density, etc. in the internal structures of semiconductors have rapidly progressed in response to demand for miniaturization, reduced weight, and increased performance in electronic equipment. Resin compositions in which silica powders with decreased average particle sizes have been blended as fillers are desired as sealing materials for such semiconductors, but as discussed previously, silica powders with small average particle sizes readily aggregate and have poor handling. Therefore, a silica powder with a small particle size which does not readily aggregate and which has a low coarse particle content and favorable handling is desired.

With respect to this problem, Patent Document 1, for example, describes a silica powder with a BET of 2 m²/g or greater and less than 30 m²/g and a content of 0.1% by mass or less of particles with a diameter of 1.5 μm or greater. However, because coarse particles are removed by wet classification in Patent Document 1, the particle size distribution and specific surface area change due to the reduction in fume components on the particle surfaces and dispersibility in resins falls. Further, Patent Document 2 presents a fine spherical silica powder having a maximum particle size distribution value in the range of 1 μm to 10 μm, wherein there is 0.01% by weight or less of coarse particle residue on a sieve with a mesh size of 45 μm. However, in the method of Patent Document 2, removing only coarse particles without altering the particle size distribution is difficult. Further, a powder with a particle size of 2.0 μm or less is not at all examined in Patent Document 1 or 2.
Patent Document 1: JP 2016-204236 A
Patent Document 2: JP 2015-86120 A

### SUMMARY OF THE INVENTION

Thus, the present invention has the purpose of providing: a silica powder with a particle size of 2.0 μm or less which does not readily aggregate, has favorable handling, and readily disperses when mixed with a resin; and a resin composition and a semiconductor sealing material comprising the silica powder.

As a result of diligent investigation, the present inventors discovered that all of the abovementioned problems can be solved if a silica powder has a maximum particle size (Dₘₐₓ) of 5.0 μm or less as measured by a grind gauge with a specific method, completing the present invention.

That is, the present invention has the following aspects.

[1] A silica powder having a volume-based cumulative size (D50) of 2.0 μm or less and a maximum particle size (Dₘₐₓ) of 5.0 μm or less measured by a grind gauge with the following method:

### (Measurement Method)

preparing a resin composition by adding 67 parts by mass of silica powder to 100 parts by mass of a bisphenol F-type liquid epoxy resin and mix-processing using a rotation-revolution mixer by rotating for three minutes and revolving for one minute at 2,000 rpm and a temperature of 30° C.; using a grind gauge with a width of 90 mm, a length of 240 mm, and a maximum depth of 100 μm on the resin composition to evaluate the degree of dispersion of the silica powder in the epoxy resin with a distribution map method and measure the maximum particle size (Dₘₐₓ) in accordance with JIS K 5600-2-5; and performing the same evaluation five times to employ the average value thereof.

[2] The silica powder described in [1], having a volume-based cumulative size (D90) of 2.5 μm or less.

[3] The silica powder described in [1] or [2], having a volume-based cumulative size (D100) of 4.7 μm or less.

[4] The silica powder described in any one of [1] to [3], having a specific surface area (BET) of 2-15 m²/g.

[5] The silica powder described in any one of [1] to [4], having a volume-based frequency of 1.0-3.0 of the volume-based cumulative size (D90), with respect to the difference between the volume-based cumulative size (D100) and the volume-based cumulative size (D90), as calculated by the following expression (1) (volume-based frequency of the volume-based cumulative size (D90))/(volume-based cumulative size (D100)-volume-based cumulative size (D90)) . . . (1).

[6] A resin composition comprising the silica powder of any one of [1] to [5], and a resin.

[7] The resin composition described in [6], wherein the resin comprises a thermosetting resin.

[8] A semiconductor sealing material formed by using the resin composition described in [6] or [7].

According to the present invention, a silica powder with a particle size of 2.0 μm or less which does not readily aggregate, has favorable handling, and readily disperses when mixed with a resin; and a resin composition and a semiconductor sealing material comprising the silica powder can be provided.

### DESCRIPTION OF EMBODIMENTS

The present invention shall be explained in more detail below, but the present invention is not limited to the following aspects. Note that herein, “−” means “ . . . or greater and . . . or less”. For example, “3-15” means 3 or greater and 15 or less. Note that herein, “powder” means “an assembly of particles”.

### [Silica Powder]

The silica powder according to the present invention is characterized by having a volume-based cumulative size (D50) of 2.0 μm or less and a maximum particle size (Dₘₐₓ) of 5.0 μm or less as measured by a grind gauge with the following method.

### (Measurement Method)

Preparing a resin composition by adding 67 parts by mass of silica powder to 100 parts by mass of a bisphenol F-type liquid epoxy resin and mix-processing using a rotation-revolution mixer by rotating for three minutes and revolving for one minute at 2,000 rpm and a temperature of 30° C., using a grind gauge with a width of 90 mm, a length of 240 mm, and a maximum depth of 100 μm on the resin composition to evaluate the degree of dispersion of the silica powder in the epoxy resin with a distribution map method and measure the maximum particle size (Dₘₐₓ) in accordance with JIS K 5600-2-5, and performing the same evaluation five times to employ the average value thereof.

The silica powder according to the present invention does not readily aggregate, handling is favorable, and the powder readily disperses when mixed with a resin.

The volume-based cumulative size (D50) (hereafter also referred to as “D50”) of the silica powder according to the present invention is 2.0 μm or less, preferably 1.5 μm or less, more preferably 0.3-1.2 μm, and especially preferably 0.4-1.0 μm. Even when D50 is 2.0 μm or less, the silica powder according to the present invention does not readily aggregate and handling is favorable. Further, because aggregation of the particles does not readily occur when mixed with a resin, dispersibility is also favorable. Note that herein, the volume-based cumulative size (D50) of the silica powder indicates a particle size where the cumulative value in a volume-based cumulative particle size distribution measured by a laser diffraction scattering method (index of refraction: 1.50) corresponds to 50%. The cumulative particle size distribution is represented by a distribution curve where the horizontal axis is the particle size (μm) and the vertical axis is the cumulative value (%). The volume-based cumulative particle size distribution according to the laser diffraction scattering method (index of refraction: 1.50) is measured using a laser diffraction scattering-type particle size distribution measuring instrument (manufactured by Beckman Coulter Co., Ltd., product name: “LS 13 320 XR”) and, using water (index of refraction: 1.33) as the solvent, carrying out a dispersion treatment for two minutes using an ultrasonic wave generator (manufactured by SONICS & MATERIALS INC., product name: “VC-505”) as a pre-treatment.

The silica powder according to the present invention has a maximum particle size (Dₘₐₓ) of 5.0 μm or less as measured by a grind gauge with this method.

The grooves in a grind gauge are sloped and gradually become shallower. Therefore, when particles with a particle size greater than the depth of the groove are present, linear impressions are left in the formed film. Accordingly, by checking the impressions in the formed film with the scale on the grind gauge to confirm, the presence or absence of aggregates and the particle size can be confirmed. In the grind gauge measurement method according to the present invention, the “maximum particle size (Dₘₐₓ)” means the value of the linear impression left at the position where the particle size is largest among the linear impressions left in the formed film on the grind gauge. In the present invention, the abovementioned evaluation is performed five times and the average value thereof is made the “maximum particle size (Dₘₐₓ)”.

As discussed previously, the grind gauge measurement is performed on a resin composition wherein the silica powder has been dispersed in a bisphenol F-type liquid epoxy resin. According to this method, the dispersibility and the degree of aggregation of the silica powder when dispersed in a resin can be evaluated. The silica powder according to the present invention has a maximum particle size (Dₘₐₓ) of 5.0 μm or less as measured by a grind gauge with this method and this means that aggregation of the silica powder within the resin is suppressed. That is, the silica powder according to the present invention readily disperses and does not readily aggregate when mixed with a resin.

It is preferred that a resin wherein the viscosity is 3,000-4,500 mPa·s (25° C.) and the epoxy equivalent is 160-175 g/eq is used as the bisphenol F-type liquid epoxy resin used in the grind gauge measurement.

The maximum particle size (Dₘₐₓ) is preferably 4.5 μm or less and especially preferably 4.0 μm or less.

The volume-based cumulative size (D90) (hereafter also referred to as “D90”) of the silica powder according to the present invention is preferably 2.5 μm or less, more preferably 2.2 μm or less, and still more preferably 2.0 μm or less. D90 indicates a particle size where the cumulative value in a volume-based cumulative particle size distribution measured with the same method as for D50 discussed previously corresponds to 90%. That is, D90 being 2.5 μm or less means that the silica powder is that in which there are fewer particles that have aggregated and coarsened.

The volume-based cumulative size (D100) (hereafter also referred to as “D100”) of the silica powder according to the present invention is preferably 4.7 μm or less, more preferably 4.2 μm or less, and still more preferably 4.0 μm or less. D100 indicates a particle size where the cumulative value in a volume-based cumulative particle size distribution measured with the same method as for D50 and D90 discussed previously corresponds to 100%. “D100 is 4.7 μm or less” means that coarse particles exceeding 4.7 μm are substantially absent in the silica powder. Note that “substantially absent” means that the ratio of coarse particles exceeding 4.7 μm in the silica powder is less than 0.1% by mass. Handling readily becomes more favorable in such a silica powder and when made into a resin composition for a semiconductor sealing material, the risk of coarse particles getting into the gaps between wiring and causing short circuit failures is more readily reduced.

The value of the volume-based frequency of the volume-based cumulative size (D90), with respect to the difference between the volume-based cumulative size (D100) and the volume-based cumulative size (D90), as calculated by the following expression (1) is preferably 1.0-3.0, more preferably 1.5-3.0, and still more preferably 2.0-3.0.

(volume-based frequency of the volume-based cumulative size(D90))/(volume-based cumulative size(D100)-volume-based cumulative size(D90)) (1)

In expression (1), “volume-based frequency of the volume-based cumulative size (D90)” (hereafter also referred to as “volume-based frequency of D90”) means the frequency of the particle size where the cumulative value in a volume-based cumulative particle size distribution measured with the laser diffraction scattering method (index of refraction: 1.50) discussed previously corresponds to 90%. If the volume-based frequency of D90 with respect to the difference between D100 and D90 is within the abovementioned range, aggregation occurs less readily and there are fewer coarse particles. Handling readily becomes more favorable in such a silica powder and when made into a resin composition for a semiconductor sealing material, the risk of coarse particles getting into the gaps between wiring and causing short circuit failures is more readily reduced.

The difference between D100 and D90 (D100-D90) is preferably 2.3 μm or less and more preferably 2.0 μm or less. If the difference between D100 and D90 is within this range, the silica powder becomes that with a narrower particle size distribution. In such a silica powder, there are fewer coarse particles and dispersibility with resins readily becomes more favorable.

The ratio between D50 and D90 (D90/D50) in the silica powder according to the present invention is preferably 2.2 or less, more preferably 2.0 or less, and still more preferably 1.4-2.0. If D90/D50 is 2.2 or less, the silica powder readily becomes that with a narrower particle size distribution. Such a silica powder is preferable because the powder less readily aggregates and handling becomes more favorable.

The ratio between D50 and D100 (D100/D50) in the silica powder according to the present invention is preferably 5.0 or less and more preferably 4.0 or less. 3.0-4.0 is still more preferable. If D100/D50 is 5.0 or less, the silica powder readily becomes that with a narrower particle size distribution. Such a silica powder is preferable because the powder less readily aggregates and handling becomes more favorable.

In the silica powder according to the present invention, the specific surface area measured with a BET method is preferably 2-15 m²/g, more preferably 3-12 m²/g, and still more preferably 3-8 m²/g. The silica powder according to the present invention is capable of having a comparatively small specific surface area while D50 is 2.0 μm or less. In the silica powder according to the present invention, the particle size distribution is comparatively narrow and the ratio of finer particles is low. Further, because aggregation of the particles is suppressed, a specific surface area in the abovementioned range is readily realized. Note that herein, measurement of the specific surface area with a BET method was performed with a “Macsorb® HM model-1208” (manufactured by MOUNTECH Co., Ltd.).

In terms of bringing the coefficients of thermal expansion of a semiconductor chip and a liquid sealing material near one another and from the perspectives of solder heat resistance, moisture resistance, and low mold wear, the silica powder according to the present invention is more preferably an amorphous silica powder manufactured with a method of melting a crystalline silica powder at a high temperature.

The silica powder according to the present invention is preferably a spherical silica powder and more preferably a spherical amorphous silica powder. As the degree of “spherical”, preferably the average sphericity is 0.85 or greater. Note that, by importing a particle image taken with a stereoscopic microscope (for example, product name: “Model SMZ-10” manufactured by Nikon Corporation), a scanning electron microscope, a transmission electron microscope, etc. into an image analysis device (manufactured by, for example, Nippon Avionics, Co., Ltd. or the like), the average sphericity can be measured and calculated as follows. That is, the projected area (A) and the perimeter (PM) of a particle are measured from a photograph. With the area of a perfect circle for the perimeter (PM) as (B), the roundness of the particle can be represented as A/B. Thus, imagining a perfect circle having a perimeter identical to the perimeter (PM) of a sample particle, PM=2πr and B=πr², so B=π×(PM/2πr)² and the sphericity of each particle can be calculated as sphericity=A/B=A×4π/(PM)². The sphericities of 200 random particles obtained in this manner can be determined and the average value thereof considered the average sphericity.

The silica powder may be treated with a surface modifier. By being treated with a surface modifier, the particles less readily aggregate and dispersibility in a resin readily becomes more favorable. When the silica powder is treated with a surface modifier, the entire surface of the particles may be modified or a portion of the surface may be modified.

The surface modifier is not particularly limited so long as the silica powder has the effects of the present invention and surface modifiers which are conventionally used as fillers in silica powders and the like can be used, as appropriate. Examples include, for instance, silane compounds, silazane compounds, aluminate coupling agents, titanate coupling agents, and the like. These may be used alone or in a combination of two or more.

### [Silica Powder Manufacturing Method]

Next, one embodiment of the manufacturing method for the silica powder according to the present invention shall be explained.

The silica powder according to the present embodiment can be manufactured by classifying a raw material powder prepared with a conventionally known method. Herein, “raw material powder” means a silica powder comprising coarse particles prior to a classification process. Further, a powder for preparing the raw material powder is referred to as a “crude raw material powder”.

Conventionally known methods can be employed as the manufacturing method for the raw material powder and examples include, for instance, methods for obtaining a raw material powder by directly supplying a crude raw material powder to high-temperature flames formed in a furnace, methods for obtaining a raw material powder by spraying a slurry comprising a crude raw material powder into flames to remove a solvent, and the like.

Methods of classifying the raw material powder are normally broadly separated into dry methods and wet methods.

Examples of dry methods include, for instance, sieve classification methods, air classification methods, and the like. Examples of wet methods include, for instance, filter classification wherein, a raw material powder having been dispersed in a solvent, the solution is passed through a filter or the like to remove coarse particles and fluid classification wherein a raw material powder is put into a fluid state and coarse particles are removed by utilizing the difference between sedimentation rates.

From the perspectives of yields not readily lowering and preventing the particle size distribution or specific surface area from changing and dispersibility in a resin falling, the manufacturing method according to the present embodiment preferably comprises air classifying the raw material powder to remove coarse particles.

Air classification is a method wherein the raw material powder is dispersed in a flow of air and the gravity and inertia of the particles, centrifugal force, and the like are utilized to remove coarse particles.

Examples of methods utilizing inertia include, for instance, impact-type classification wherein a guide vane or the like is provided inside a classification device to create a rotational flow of air and when the raw material powder to which force has been imparted by the flow of air is bent into a curve, coarse particles are removed; semi-free vortex centrifuge-type classification wherein centrifugal force is made to act on the raw material powder to classify the same; Coandă-type classification utilizing the Coandă effect; and the like. Further, examples of classification devices utilizing inertia include cascade impactors, a Viable® Impactor, an Aerofine® Classifier, an Eddy Classifier®, an Elbow-Jet Classifier®, a HIPREC® Classifier, Coanda blocks, and the like.

Examples of methods utilizing centrifugal force include, for instance, methods wherein spiral air flows are utilized to remove coarse particles. Examples of devices include free vortex-type devices and forced vortex-type devices. Examples of free vortex-type devices include cyclones without guide vanes, multistage cyclones, a Turboplex® Classifier which uses secondary air to promote the elimination of aggregation, dispersion separators provided with guide vanes to enhance classification precision, a MICROSPIN® Classifier, a Micro Cut® Classifier, and the like. Examples of forced vortex-type devices include a Turbo® Classifier, a DONASELEC®, and the like in which centrifugal force is made to act upon particles by a rotating body within the device and classification precision is enhanced by further creating another air flow within the device.

From the perspectives of production efficiency and classification precision, the manufacturing method according to the present embodiment is preferably air classification utilizing inertia and more preferably comprises classifying the raw material powder by air classification utilizing the Coanda effect. Further, from the perspective of classification precision, the air flow temperature is preferably less than 150° C., more preferably 40-130° C., and still more preferably 60-120° C.

The manufacturing method for the silica powder according to the present embodiment may, for example, have the following steps:
(i) a step for pulverizing and classifying an ore to obtain a crude raw material powder, as necessary;
(ii) a step for supplying the crude raw material powder to high-temperature flames within a reactor vessel to make a raw material powder (melt powder); and
(iii) treating the raw material powder at an air flow temperature less than 150° C. with air classification utilizing the Coandă effect to obtain a silica powder wherein D50 is 2.0 μm or less and the maximum particle size (Dₘₐₓ) is 5.0 μm or less as measured with a grind gauge and the abovementioned method.
   <Step (i)>

The raw material used in step (i) is preferably of high purity (for example, a purity of 95% or greater). Examples of the raw material include metallic silicon, silica stone, and the like. These may be used alone or in a combination of two or more. Among these, comprising metallic silicon is more preferred. With regard to pulverization, a crude raw material powder having a desired particle size is prepared by pulverizing with a pulverizer such as a vibrating mill or a ball mill. Note that from the perspectives of handleability, oxidation, and sphericalization, D50 of the crude raw material powder is preferably 5-40 μm and more preferably 5-20 μm.

<Step (ii)>

In step (ii), the crude raw material powder obtained in step (i) is sprayed into high-temperature flames formed by a combustible gas and a supporting gas using a burner and melt-sphericalized at a temperature greater than or equal to the melting point or boiling point of the crude raw material powder (for example, a temperature of 1600° C. or greater in the case of silica (silica stone)), and classified and repaired while being cooled to obtain a sphericalized raw material powder (melt powder). Further, in the case of metallic silicon, a metal powder slurry is supplied to high-temperature flames comprising a combustible gas and a supporting gas in a manufacturing furnace at a temperature of 2400° C. or greater and a raw material powder is obtained by vaporizing and oxidizing the metal powder in the flames. In step (ii), D50 of the raw material powder is preferably 0.2-2.0 μm and more preferably 0.2-1.5 μm.

Hydrocarbon-based gases such as acetylene, ethylene, propane, butane, and methane; gaseous fuels such as LPG, LNG, and hydrogen; and liquid fuels such as kerosene and heavy oil can be used as the combustible gas. Oxygen, oxygen-rich cooling gases, and air can be used as the supporting gas.

In step (ii), D50 of the raw material powder may be adjusted by adjusting the amount of powder supplied, the powder temperature, the temperatures of the combustible gas and the supporting gas, etc.

<Step (iii)>

In step (iii), the raw material powder obtained in step (ii) is treated at an air flow temperature less than 150° C. with air classification utilizing the Coanda effect to obtain a silica powder wherein D50 is 2.0 μm or less and the maximum particle size (Dₘₐₓ) is 5.0 μm or less as measured with a grind gauge and the abovementioned method.

As discussed previously, the air flow temperature is more preferably 40-130° C. and still more preferably 60-120° C. The gas species used in the air flow may be any of air, oxygen, nitrogen, helium, argon, carbon dioxide, etc. In setting the volume-based cumulative size (D50) of the silica powder to 2.0 μm or less, this may be adjusted by introducing nitrogen from the perspective of aggregation less readily occurring. The flow rate of the air flow is the flow rate at the Coanda block inlet and is preferably set to less than 80 m/s, more preferably 30-75 m/s, and still more preferably 35-50 m/s. By combining these conditions, wear which occurs due to friction with the device is suppressed, dispersibility of particles in the air flow is further increased, and the Coandă effect is readily improved.

### [Resin Composition]

The resin composition according to the present invention comprises the silica powder discussed above and a resin.

The content of the silica powder in the resin composition is not particularly limited and can be adjusted, as appropriate, according to the purpose. From the perspectives of thermal resistance, the coefficient of thermal expansion, etc., the ratio of the silica powder in the resin composition is preferably 40-90% by mass and more preferably 70-90% by mass with respect to the total mass of the resin composition. Because the silica powder according to the present invention has a D50 of 2.0 μm or less and a maximum particle size (Dₘₐₓ) of 5.0 μm or less as measured with a grind gauge and the abovementioned method, dispersibility in the resin is favorable. Such a resin composition can be suitably used as a semiconductor sealing material or a substrate for semiconductor packaging.

### (Resin)

A thermosetting resin is preferred as the resin. The thermosetting resin is not particularly limited so long as the resin is normally used in the field of semiconductor sealing materials. For instance, examples include: epoxy resins; silicone resins; phenol resins; melamine resins; urea resins; unsaturated polyester resins; fluorine resins; polyimide-based resins such as polyimide resins, polyamideimide resins, and polyetherimide resins; polyester-based resins such as polybutylene terephthalate resins and polyethylene terephthalate resins; polyphenylene sulfide resins; wholly aromatic polyester resins; polysulfone resins; liquid crystal polymer resins; polyethersulfone resins; polycarbonate resins; maleimide-modified resins; ABS resins; AAS resins (acrylonitrile-acrylic rubber-styrene resins); AES resins (acrylonitrile-ethylene-propylene-diene rubber-styrene resins); and the like. These may be used alone or in a combination of two or more. Among these, comprising an epoxy resin is more preferred.

The epoxy resin is not particularly limited and examples include, for instance, phenol novolac-type epoxy resins, ortho-cresol novolac-type epoxy resins, resins in which a novolac resin of a phenol and an aldehyde has been epoxidated, glycidyl ether-type epoxy resins such as bisphenol A, bisphenol F, and bisphenol S, glycidyl ester acid epoxy resins (bisphenol-type epoxy resins) obtained by a reaction between a polybasic acid such as phthalic acid or dimer acid and epichlorohydrin, linear aliphatic epoxy resins, alicyclic epoxy resins, heterocyclic epoxy resins, alkyl-modified multifunctional epoxy resins, β-naphthol novalac-type epoxy resins, 1,6-dihydroxynaphthalene-type epoxy resins, 2,7-dihydroxynaphthalene-type epoxy resins, bishydroxybiphenyl-type epoxy resins, and further epoxy resins wherein a halogen such as bromine has been introduced in order to impart flame retardance. These may be used alone or in a combination of two or more. Among these, comprising at least one epoxy resin selected from alicyclic epoxy resins and bisphenol-type epoxy resins such as bisphenol A-type epoxy resins and bisphenol F-type epoxy resins is more preferred.

### (Curing Agent)

When an epoxy resin is included as the resin, the resin composition further comprising a curing agent is preferred. Examples of the curing agent include, for instance, novolac-type resins obtained by reacting one or a mixture of two or more selected from the group consisting of phenol, cresol, xylenol, resorcinol, chlorophenol, t-butyl phenol, nonylphenol, isopropylphenol, octylphenol, etc. with formaldehyde, paraformaldehyde, or paraxylene in the presence of an oxidation catalyst, polyparahydroxystyrene resins, bisphenol compounds such as bisphenol A and bisphenol S, tri-functional phenols such as pyrogallol or phloroglucinol, acid anhydrides such as maleic anhydride, phthalic anhydride, and pyromellitic anhydride, aromatic amines such as metaphenylenediamine, diaminodiphenylmethane, and diaminodiphenylsulfone, and the like.

The content of the curing agent is preferably blended such that the active hydrogen equivalent (or anhydride equivalent) of the curing agent with respect to one epoxy equivalent of the epoxy resin is 0.01-1.25.

### (Other Additives)

So long as the effects of the present invention are not hindered, curing promoters, release agents, coupling agents, colorants, and the like can be blended with the resin composition.

The curing promoter is not particularly limited and examples include 1,8-diazabicyclo(5,4,0)undecene-7, triphenylphosphine, benzyldimethylamine, and 2-methylimidazole, and the like.

Examples of release agents include natural waxes, synthetic waxes, metal salts of straight-chain fatty acids, acid amides, esters, paraffin, and the like.

Examples of coupling agents include silane coupling agents. Examples of silane coupling agents include epoxysilanes such as γ-glycidoxypropyltrimethoxysilane and β-(3,4-epoxycyclohexyl)ethyltrimethoxysilane; aminosilanes such as aminopropyltriethoxysilane, ureidopropyltriethoxysilane, and N-phenylaminopropyltrimethoxysilane; hydrophobic silane compounds such as phenyltrimethoxysilane, methyltrimethoxysilane, and octadecyltrimethoxysilane; mercaptosilanes; and the like.

One aspect of the resin composition according to the present invention is a resin composition comprising the silica powder according to the present invention and a bisphenol F-type epoxy resin, wherein the maximum particle size (Dₘₐₓ) is 5.0 μm or less on a grind gauge as measured under the conditions described below. The maximum particle size (Dₘₐₓ) may be 4.0 μm.

### (Measurement Method)

Preparing a resin composition by adding 67 parts by mass of silica powder to 100 parts by mass of a bisphenol F-type liquid epoxy resin and mix-processing using a rotation-revolution mixer by rotating for three minutes and revolving for one minute at 2,000 rpm and a temperature of 30° C., using a grind gauge with a width of 90 mm, a length of 240 mm, and a maximum depth of 100 μm on the resin composition to evaluate the degree of dispersion of the silica powder in the epoxy resin with a distribution map method and measure the maximum particle size (Dₘₐₓ) in accordance with JIS K 5600-2-5, and performing the same evaluation five times to employ the average value thereof.

### <Resin Composition Manufacturing Method>

The manufacturing method for the resin composition is not particularly limited and the resin can be manufactured by agitating, dissolving, mixing, or dispersing predetermined amounts of the materials. The device for mixing, agitating, dispersing, etc. these mixtures is not particularly limited and a mortar machine, a three-roll mill, a ball mill, a planetary mixer, or the like equipped with agitation and heating devices can be used. Further, these devices may be used in combination, as appropriate.

### [Semiconductor Sealing Material]

The semiconductor sealing material according to the present invention is formed using the resin composition of the present invention.

Specifically, the resin composition is first kneaded with a roll, extruder, or the like while being heated and the kneaded material is stretched into sheet-like shape and cooled. The semiconductor sealing material can then be obtained as a ground material of the resin composition by pulverizing, by cutting following linear extrusion of the kneaded material and cooling, and the like. The ground material may be molded into a shape such as a tablet shape or a pellet shape.

Conventionally known methods such as, for example, a transfer molding method or a compression molding method can be employed as the method for sealing a semiconductor using the semiconductor sealing material according to the present invention.

Examples of transfer molding methods include, for instance, a method comprising filling a pot provided in a mold of a transfer molding machine with a tablet-shaped semiconductor sealing material, heating and melting the material, and then pressurizing with a plunger and further heating to cure the sealing material.

Further, examples of compression molding methods include, for instance, a method comprising directly disposing a pellet-shaped or tablet-shaped sealing material in a mold and melting the same, then immersing bonded chips or wafers in the molten resin and heat-curing.

### EXAMPLES

The present invention shall be explained in more detail below by providing examples, but the present invention is not limited by the following descriptions.

### Examples 1-4 and Comparative Examples 1-7

(Manufacturing of Raw Material Powders: Steps (i) and (ii))

Raw material powders were manufactured using a device formed by installing, on the apex portion of a manufacturing furnace, a burner with a triple-layer coiled pipe structure wherein, in this order from the outermost portion, a combustible gas supply pipe, a supporting gas supply pipe, and a metallic silicon powder slurry supply pipe are assembled and connecting the lower portion of the manufacturing furnace to a classification and capture system (the generated particles are attracted by a blower and captured with a bag filter) such as a cyclone. Note that three outer peripheral burners which form outer peripheral flames are further installed on the outer periphery of the burner. LPG was supplied from the combustible gas supply pipe at 7 Nm³/hr and oxygen was supplied from the supporting gas supply pipe at 12 Nm³/hr to form high-temperature flames in the manufacturing furnace. A metallic silicon slurry prepared by dispersing a metallic silicon powder (average particle size (D50): 10 μm) in methyl alcohol was supplied to the flames from the metallic silicon powder slurry supply pipe using a slurry pump and the generated raw material powder (spherical silica powder) was captured by the cyclone or bag filter at a powder temperature of 110° C. to 200° C. Note that the particle size and specific surface area of the raw material powder were adjusted by controlling the metallic silicon concentration in the furnace by adjusting the slurry concentration. By these operations, powders with D50s of 0.5 μm, 0.7 μm, 1.0 μm, 1.5 μm, 1.9 μm, and 2.6 μm were obtained.

(Classification of Raw Material Powders: Step (iii))

The raw material powders obtained above were classified under the conditions shown in Table 1 and the silica powders of the respective examples were obtained. In the classification operation, the raw material powder was fed into an air classifier having a blower Coanda block structure (manufactured by MATSUBO Corporation, model name: “Elbow-Jet Classifier”), air-classified, and then captured in a bag filter. Nitrogen gas or air (dew-point temperature: −5° C.) was used as the gas used in the air flow. Further, the gas temperature of the air flow and the flow rate at the Coanda portion were as shown in Table 1.

### (Grind Gauge Measurement Method)

The maximum particle size (Dₘₐₓ) of the silica powder obtained in each example was measured under the following conditions.

Resin compositions were prepared by adding 67 parts by mass of silica powder to 100 parts by mass of a bisphenol F-type liquid epoxy resin (manufactured by Mitsubishi Chemical Corporation, product name: “807”, viscosity: 3,000-4,500 mPa·s, epoxy equivalent: 160-175 g/eq.) and mix-processing using a rotation-revolution mixer (manufactured by THINKY CORPORATION, product name: “ARE-310”) by rotating for three minutes and revolving for one minute at 2,000 rpm and a temperature of 30° C. Using a grind gauge with a width of 90 mm, a length of 240 mm, and a maximum depth of 100 μm on the obtained resin compositions, the degree of dispersion of the silica powder in the epoxy resin was evaluated with a distribution map method and the maximum particle size (Dₘₐₓ) was measured in accordance with JIS K 5600-2-5. Further, the same evaluation was performed five times and the average value thereof was employed. The results are shown in Table 1.

### (Measurement of Volume-Based Cumulative Sizes (D50, D90, and D100))

A dispersion process using water as the solvent (index of refraction: 1.33) and using an ultrasonic wave generator (manufactured by SONICS & MATERIALS INC., product name: “VC-505”) was performed for two minutes as pre-processing on the silica powder obtained in each example and then the volume-based cumulative particle size distribution according to a laser diffraction scattering method was measured using a particle size distribution measuring instrument (manufactured by Beckman Coulter Co., Ltd., product name: “LS 13 320 XR”). Further, calculation was performed by fitting the D90 volume-based frequency and the values of D100 and D90 into abovementioned expression (1). The results are shown in Table 1.

### (Measurement of Specific Surface Area (BET))

1.0 g of the silica powder obtained in each example was measured, put in a cell for measurement, and following pre-processing, the BET specific surface area was measured using nitrogen gas. A “Macsorb® HM model-1208” (manufactured by MOUNTECH Co., Ltd.) was used as the measuring instrument. The specific surface area was measured under the following conditions. The results are shown in Table 1.
Degassing temperature: 300° C.
Degassing time: 18 min.
Cooling time: 4 min.

TABLE 1

| | | | | | | | COMPAR- | COMPAR- |
|---|---|---|---|---|---|---|---|---|
| | | | | | | | ATIVE | ATIVE |
| | | | EXAM- | EXAM- | EXAM- | EXAM- | EXAM- | EXAM- |
| TABLE 1 | | | PLE 1 | PLE 2 | PLE 3 | PLE 4 | PLE 1 | PLE 2 |
| MANUFACTURING | RAW MATERIAL | (μm) | 1.0 | 0.7 | 1.5 | 0.5 | 1.0 | 1.0 |
| CONDITIONS | POWDER D50 | | | | | | | |
| | PRESENCE OR | (—) | PRESENT | PRESENT | PRESENT | PRESENT | ABSENT | PRESENT |
| | ABSENCE OF | | | | | | | |
| | CLASSIFICATION | | | | | | | |
| | TYPE OF GAS DURING | (—) | NITROGEN | NITROGEN | NITROGEN | NITROGEN | — | AIR |
| | CLASSIFICATION | | | | | | | |
| | AIR FLOW GAS | (° C.) | 120 | 60 | 60 | 120 | — | 120 |
| | TEMPERATURE | | | | | | | |
| | FLOW RATE AT | (m/s) | 45 | 45 | 45 | 45 | — | 80 |
| | COANDĂ PORTION | | | | | | | |
| EVALUATION | D50 | (μm) | 0.9 | 0.6 | 1.5 | 0.4 | 1.0 | 0.9 |
| RESULTS | GRIND GAUGE (Dₘₐₓ) | | 4.0 | 5.0 | 5.0 | 5.0 | 58.0 | 12.0 |
| | D90 | | 1.5 | 2.2 | 2.7 | 0.8 | 2.1 | 2.2 |
| | D100 | | 2.9 | 4.3 | 4.7 | 1.8 | 5.6 | 5.6 |
| | (VOLUME FREQUENCY | (—) | 2.7 | 1.5 | 1.6 | 2.7 | 0.8 | 0.8 |
| | OF D90)/(D100 − D90) | | | | | | | |
| | D90/D50 | | 1.7 | 3.7 | 1.8 | 2.0 | 2.3 | 2.5 |
| | D100/D50 | | 3.4 | 7.2 | 3.1 | 4.5 | 6.2 | 6.2 |
| | BET | (m²/g) | 6 | 7 | 3 | 12 | 6 | 6 |

| | | | COMPAR- | COMPAR- | COMPAR- | COMPAR- | COMPAR- |
|---|---|---|---|---|---|---|---|
| | | | ATIVE | ATIVE | ATIVE | ATIVE | ATIVE |
| | | | EXAM- | EXAM- | EXAM- | EXAM- | EXAM- |
| TABLE 1 | | | PLE 3 | PLE 4 | PLE 5 | PLE 6 | PLE 7 |
| MANUFACTURING | RAW MATERIAL | (μm) | 1.9 | 2.6 | 0.5 | 0.7 | 1.0 |
| CONDITIONS | POWDER D50 | | | | | | |
| | PRESENCE OR | (—) | PRESENT | PRESENT | PRESENT | PRESENT | PRESENT |
| | ABSENCE OF | | | | | | |
| | CLASSIFICATION | | | | | | |
| | TYPE OF GAS DURING | (—) | AIR | AIR | AIR | AIR | NITROGEN |
| | CLASSIFICATION | | | | | | |
| | AIR FLOW GAS | (° C.) | 60 | 120 | 60 | 60 | 120 |
| | TEMPERATURE | | | | | | |
| | FLOW RATE AT | (m/s) | 45 | 45 | 45 | 80 | 80 |
| | COANDĂ PORTION | | | | | | |
| EVALUATION | D50 | (μm) | 1.7 | 2.3 | 0.3 | 0.5 | 0.4 |
| RESULTS | GRIND GAUGE (Dₘₐₓ) | | 53.0 | 19.0 | 76.0 | 30.0 | 95.0 |
| | D90 | | 3.8 | 3.9 | 1.9 | 2.3 | 0.7 |
| | D100 | | 8.1 | 6.8 | 5.1 | 5.1 | 2.4 |
| | (VOLUME FREQUENCY | (—) | 0.9 | 2.0 | 0.6 | 0.8 | 2.3 |
| | OF D90)/(D100 − D90) | | | | | | |
| | D90/D50 | | 2.2 | 1.7 | 5.9 | 4.4 | 1.7 |
| | D100/D50 | | 4.7 | 2.9 | 16.0 | 9.9 | 5.8 |
| | BET | (m²/g) | 6 | 30 | 24 | 17 | 9 |

As shown in Table 1, in the silica powders of Examples 1-4, while the D50 was 2.0 μm or less, the maximum particle size (Dₘₐₓ) measured with a grind gauge was 5.0 μm or less. That is, silica powders that readily disperse and do not readily aggregate even when mixed with a resin were obtained. Further, it is understood that such silica powders would be more readily obtained by classifying the raw material particles using nitrogen gas at a lower gas temperature and a lower flow rate. Moreover, according to the results for Comparative Examples 1-7, in cases where a classification process was not carried out and in cases where the classification process was carried out in air, the silica powders readily aggregated in the resin.

### INDUSTRIAL APPLICABILITY

As discussed above, the silica powder according to the present invention has the characteristics of not readily aggregating, handling being favorable, and readily dispersing when mixed with a resin while having a D50 of 2.0 μm or less. A resin composition comprising such a silica powder can be suitably used as a semiconductor sealing material.

1. A silica powder having a volume-based cumulative size (D50) of 2.0 μm or less and a maximum particle size (Dₘₐₓ) of 5.0 μm or less as measured by a grind gauge with the following method:
preparing a resin composition by adding 67 parts by mass of silica powder to 100 parts by mass of a bisphenol F-type liquid epoxy resin and mix-processing by utilizing a rotation-revolution mixer by rotating for three minutes and revolving for one minute at 2,000 rpm and a temperature of 30° C.; by utilizing a grind gauge with a width of 90 mm, a length of 240 mm, and a maximum depth of 100 μm on the resin composition to evaluate the degree of dispersion of the silica powder in the epoxy resin with a distribution map method and measure the maximum particle size (Dₘₐₓ) in accordance with JIS K 5600-2-5; and performing the same evaluation five times to employ the average value thereof.

2. The silica powder according to claim 1, having a volume-based cumulative size (D90) of 2.5 μm or less.

3. The silica powder according to claim 1, having a volume-based cumulative size (D100) of 4.7 μm or less.

4. The silica powder according to claim 1, having a specific surface area (BET) of 2-15 m²/g.

5. The silica powder according to claim 1, having a volume-based frequency value of 1.0-3.0 of the volume-based cumulative size (D90), with respect to the difference between the volume-based cumulative size (D100) and the volume-based cumulative size (D90), as calculated by the following expression (1)
(volume-based frequency of the volume-based cumulative size(D90))/(volume-based cumulative size(D100)-volume-based cumulative size(D90)) (1).

6. A resin composition comprising the silica powder according to claim 1 and a resin.

7. The resin composition according to claim 6, wherein the resin comprises a thermosetting resin.

8. A semiconductor sealing material formed by utilizing the resin composition according to claim 6.

9. The silica powder according to claim 2, having a volume-based cumulative size (D100) of 4.7 μm or less.

10. The silica powder according to claim 2, having a specific surface area (BET) of 2-15 m²/g.

11. The silica powder according to claim 2, having a volume-based frequency value of 1.0-3.0 of the volume-based cumulative size (D90), with respect to the difference between the volume-based cumulative size (D100) and the volume-based cumulative size (D90), as calculated by the following expression (1)
(volume-based frequency of the volume-based cumulative size(D90))/(volume-based cumulative size(D100)-volume-based cumulative size(D90)) (1).

12. A resin composition comprising the silica powder according to claim 2, and a resin.
